(19) United States
(12) Patent Application Publication
(10) Pub. No.: US 2013/0076437 A1
(43) Pub. Date: Mar. 28, 2013

(54) COMBINED PREDISTORTER AND FEEDFORWARD CORRECTOR APPARATUS SUITABLE FOR USE IN A TRANSMITTER

(71) Applicants: Russell Smiley, Richmond (CA); Chunlong Bai, Ottawa (CA)

(72) Inventors: Russell Smiley, Richmond (CA); Chunlong Bai, Ottawa (CA)

(73) Assignee: TELEFONAKTIEBOLAGET L M ERICSSON (PUBL), Stockholm (SE)

(21) Appl. No.: 13/240,534

(22) Filed: Sep. 22, 2011

(51) Int. Cl. H03F 1/26

(52) U.S. Cl. 330/149

(57) ABSTRACT

In accordance with the present disclosure, there is provided a predistorter combined with a feedforward corrector that addresses power dissipation of the feedforward error path while maintaining a sufficiently simple digital predistortion model so as to further minimize power dissipation without sacrificing linearity.

### CROSS-REFERENCE TO RELATED APPLICATIONS

This is the first application filed for this invention.

### TECHNICAL FIELD

The present application relates to power amplifier linearization and power dissipation and, more particularly, to a combined predistorter and feedforward corrector apparatus suitable for use in a transmitter.

### BACKGROUND OF THE APPLICATION

FIG. 1 is an exemplary bi-directional radio communication system including two radio systems each having a transmitter and receiver. A radio system needs to transmit signals so that a receiver can receive information. While it is conceivable for a communications system to have one transmitter and one or more receivers, or multiple transmitters and only one receiver, there are many communication systems that require the radio systems to communicate in both directions and it is these systems that this disclosure is mostly concerned with, although there is nothing about this invention that limits it's scope exclusively to bi-direction communications systems. It is potentially applicable to any radio system where a radio transmitter is required. Communicating bi-directionally requires a transmitter and receiver at each radio system endpoint, as shown in FIG. 1.

A transmitter is designed to transmit a large enough power signal to overcome the loss inherent in transmitting over a distance so that the signal can still be received. The electronic equipment used to amplify small signals to a sufficiently high level for transmission is called a power amplifier.

Radio system transmitters are required to meet specifications for the signal levels at frequencies off the intended transmission frequencies. One requirement is called adjacent channel power, or a related measure called code domain power, and is related directly to the linearity of the amplifier, or the ability of the amplifier to accurately reproduce an amplified version of the input signal at the output.

At a circuit level, linearity may be achieved by biasing transistors such that they behave in a very linear fashion, but given the nature of existing transistor and more generally amplifier technology, this has a cost in terms of very low operating efficiency. Modern power amplifiers try to use the amplifying devices in such a way that they are operating at maximum efficiency, resulting in poor linearity, and subsequently using additional so-called “linearization” circuitry to correct the nonlinear behaviour.

Various linearization schemes have various tradeoffs in terms of linearity, efficiency and versatility, or robustness, such as for example analog predistortion linearization, digital predistortion linearization, and feedforward linearization.

For example, US20020131522A1 discloses a method and apparatus for the digital predistortion linearization, frequency response compensation linearization and feedforward linearization of a transmit signal wherein feeding back of measurement variables, enables to achieve a very high level of linearization effect, but this may be at the expense of power dissipation.

Similarly, WO1999045640A1 discloses a predistorter wherein the feedback arrangement is operated in real time, and takes into account time dependent changes that may result from temperature changes, aging of amplifier components or power supply fluctuations, but the linearity achieved may be ath the expense of power dissipation.

FIG. 2 is an exemplary linearizer including an analog predistorter. Analog predistortion linearization uses the characteristics of analog devices to generate a signal response that approximates the nonlinearity of the unlinearized power amplifier. Analog circuits can achieve very low power dissipation, but it may be difficult to achieve high accuracy for the predistortion functions, resulting in poor nonlinearity correction.

FIG. 3 is an exemplary linearizer including digital predistortion. Digital predistortion linearization can achieve high efficiency, but good linearity may require an accurate model of the nonlinearities of the power amplifier and such models may be difficult to achieve good accuracy depending on the nature of the transistor devices and circuits used. High complexity in a digital predistortion algorithm may correlate to relatively high power dissipation in the digital processing circuitry and may limit total efficiency achieved, depending on the output power of the amplifier system.

FIG. 4 is an exemplary feedforward linearizer. Feedforward linearization may theoretically linearise any nonlinear behaviour, but practical limitations to delay, amplitude and phase imbalance may limit the total amount of correction achievable. Also, the efficiency improvement may be modest due to relatively high power dissipation in the error amplifier.

### SUMMARY

In accordance with the present disclosure, there is provided a combined predistorter and feedforward corrector apparatus suitable for use in a transmitter for improving at least one of power dissipation and linearity in the transmitter. The apparatus includes a predistorter, for receiving an input signal, and for providing a predistorter signal by performing as much linearization as necessary to predistort the input signal within the predetermined bounds of linearizer efficiency and correction required by the transmitter. A power amplifier is also provided, for receiving the predistorted signal, and for providing an amplified predistorted signal by amplifying the predistorted signal, connected to said predistorter. A feedforward corrector is also provided, for receiving the input signal, and for providing a correction signal by correcting any remaining distortion that the power amplifier produces that the predistorter did not correct. A summator is connected to said feedforward corrector, and connected to said power amplifier, for receiving the amplified predistorted signal and the correction signal, and for providing an output signal by summing the amplified predistorted signal and the correction signal.

In some embodiments, an actuator is provided, for receiving the input signal and for providing at least one of a predistorted input signal and a corrected input signal.

In some embodiments, an adjustment block is provided for receiving an adjustment input signal comprising at least one of the input signal and an input adjusted amplified predistorted signal, and for providing a respective one of an adjusted input signal and an unamplified correction signal respectively, by adjusting at least one of gain, phase, and delay of the adjustment input signal.

In some embodiments, an adaptor is provided, for receiving at least one of the input signal, the output signal, the amplified predistorted signal, and an input adjusted amplified predistorted signal, and for providing an adapted signal which is adapted to a change in the electronics environment to be used by one of an actuator and an adjustment block.

In some embodiments, an error amplifier is provided, for receiving an unamplified error signal including at least one of an unamplified correction signal, an adjusted input signal, and a corrected input signal, and for providing the correction signal by amplifying the unamplified error signal.

In some embodiments, a second summator is provided connected to the adjustment block, and connected to the power amplifier, for receiving the amplified predistorted signal and an adjusted input signal, and for providing an input adjusted amplified predistorted signal by summing the amplified predistorted signal and the adjusted input signal.

In some embodiments, an upconverter is provided for receiving an upconverter input signal including at least one of the predistorted input signal, an adjusted input signal, and a corrected input signal, and for upconverting the upconverter input signal.

In some embodiments, a downconverter is provided for receiving a downconverter input signal comprising at least one of the amplified predistorted signal, the output signal, and an input adjusted amplified predistorted signal, and for downconverting the downconverter input signal.

In some embodiments, a controller is provided connected to the feedforward corrector, and connected to the predistorter, for sensing at least one of the output signal, and the amplified predistorted signal, the input adjusted amplified predistorted signal, and for controlling at least one adaptor.

In accordance with a second aspect of the present disclosure, there is provided a method of controlling the apparatus recited above. The method includes the act of sensing signals, including at least one of the output signal, and the amplified predistorted signal. The method then proceeds with the act of determining if predistorter linearization is sufficient enough to predistort the input signal within the predetermined bounds of linearizer efficiency and correction required by the transmitter. If predistorter linearization is determined to be sufficient enough, the amount of feedforward correction in the feedforward corrector is decreased. Conversely, if predistorter linearization is determined not to be sufficient enough, then the amount of feedforward correction in the feedforward corrector is increased.

In some embodiments, the act of decreasing the amount of feedforward correction in the feedforward corrector includes the act of disabling the feedforward corrector.

In some embodiments, the act of increasing the amount of feedforward correction in the feedforward corrector includes the act of enabling the feedforward corrector.

### BRIEF DESCRIPTION OF THE DRAWINGS

A complete understanding of the present application may be obtained by reference to the accompanying drawings, when considered in conjunction with the subsequent, detailed description, in which:

FIG. 1 is an exemplary bi-directional radio communication system including two radio systems each having a transmitter and receiver;

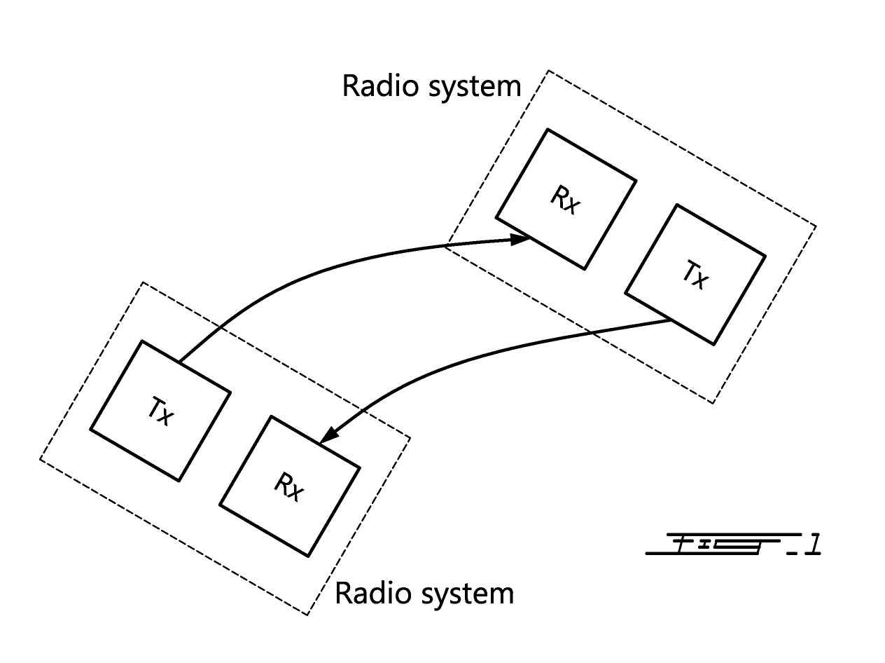

FIG. 2 is an exemplary linearizer including an analog predistorter;

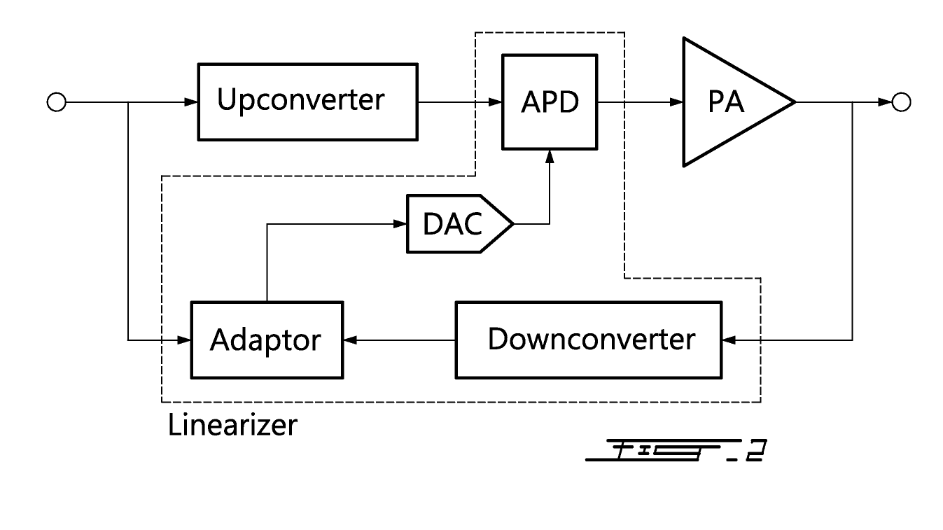

FIG. 3 is an exemplary linearizer including digital predistortion;

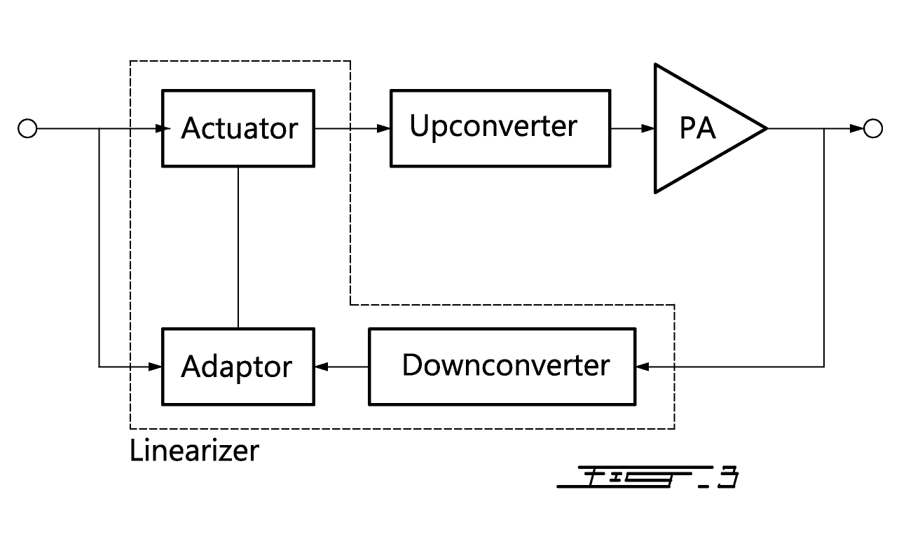

FIG. 4 is an exemplary feedforward linearizer;

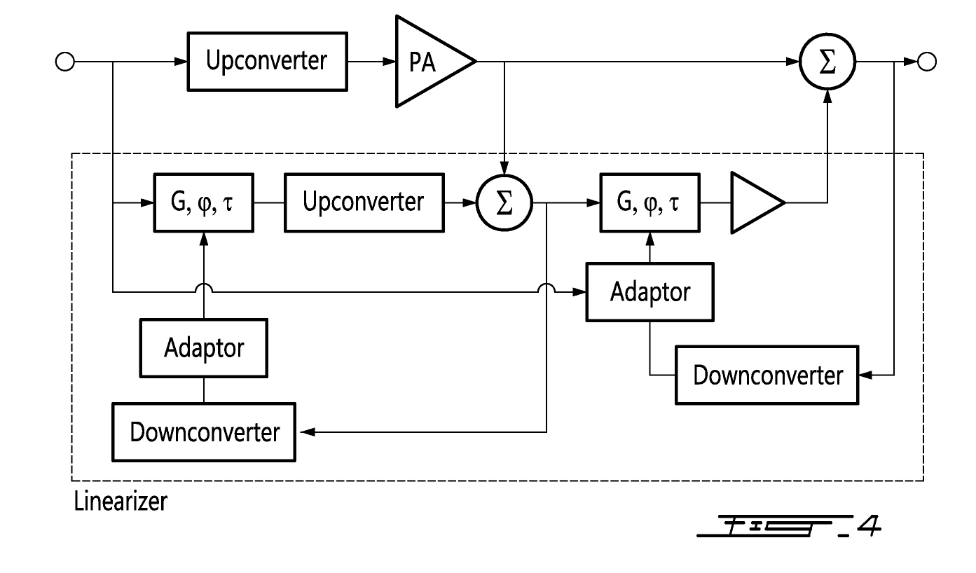

FIG. 5 is an exemplary predistorter combined with feedforward correction, in accordance with an embodiment of the present application;

FIG. 6 is an exemplary predistorter combined with feedforward correction, in accordance with an embodiment of the present application;

FIG. 7 is an exemplary predistorter combined with feedforward correction, in accordance with an embodiment of the present application;

FIG. 8 is an exemplary predistorter combined with feedforward correction, in accordance with an embodiment of the present application;

FIG. 9 is an exemplary predistorter combined with feedforward correction, in accordance with an embodiment of the present application; and

FIG. 10 is an exemplary flowchart, in accordance with an embodiment of the present application.

For purposes of clarity and brevity, like elements and components will bear the same designations and numbering throughout the Figures.

### DETAILED DESCRIPTION OF THE DRAWINGS

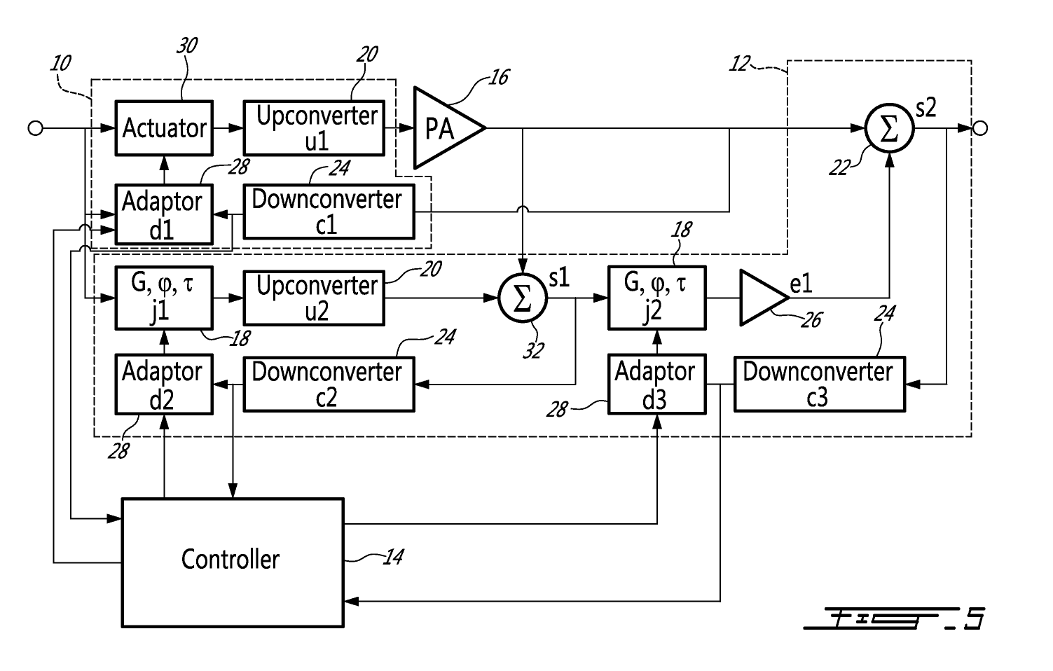

Referring to the drawings, one exemplary embodiment of the apparatus is shown in FIG. 5. The embodiment of the apparatus illustrated includes a predistorter 10, a power amplifier 16, a feedforward corrector 12, a summator 22 s2 and a controller 14. The predistorter 10 is combined with a feedforward corrector 12 such that the predistorter 10 performs as much linearization as necessary within the bounds of linearizer efficiency and correction required. The controller 14 senses signals and controls the predistorter 10 and feedforward corrector 12 in order to ensure that If the power amplifier 16 is such that the predistorter 10 is not sufficient to complete linearization, then the feedforward corrector 12 will correct any remaining distortion in the system. Operationally, an input signal is received by the predistorter 10 and by the feedforward corrector 12. The predistorter 10 provides a predistorted signal to the power amplifier 16. The power amplifier 16 and the feedforward corrector 12 provide an amplified predistorted signal and a correction signal respectively to the summator 22. The summator 22 provides the output signal by adding the amplified predistorted signal and the correction signal. The controller 14 ensures that the feedforward corrector 12 corrects any remaining distortion that the power amplifier 16 produces that the predistorter 10 did not correct.

In the embodiment shown in FIG. 5, the predistorter 10 includes an actuator 30, an upconverter 20 u1, an adaptor 28 d1, and a downconverter 24 c1. The actuator 30 is provided for receiving the input signal and for providing a predistorted input signal. The upconverter 20 u1 is provided for receiving an upconverter 20 input signal, which in this case is the predistorted input signal, and for upconverting the upconverter 20 input signal so that the predistorted input signal (now upconverted) can be amplified by the power amplifier 16. The downconverter 24 c1 is provided for receiving a downconverter 24 input signal, which in this case is the amplified predistorted signal, and for downconverting the downconverter 24 input signal. The predistorter 10 also includes an adaptor 28 d1 provided for receiving the input signal and the (downconverted) amplified predistorted signal, and for providing an adapted signal which is adapted to a change in the electronics environment to be used by the actuator 30.

In the embodiment shown in FIG. 5, the feedforward corrector 12 includes an adjustment block 18 j1, an upconverter 20 u2, a second summator 32 s1, an adjustment block 18 j2, an error amplifier 26, an adaptor 28 d2, a downconverter 24 c2, an adaptor 28 d3, and a downconverter 24 c3. Signal flow includes a feedforward path, two feedback paths, as well as sensing and control.

In the embodiment shown in FIG. 5, the feedforward path begins at the adjustment block 18 j1, provided for receiving an adjustment input signal, which in this case is the input signal of the apparatus, and for providing an adjusted input signal, by adjusting at least one of gain, phase, and delay of the adjustment input signal. The upconverter 20 u2 is provided for receiving an upconverter 20 input signal, which in this case is the adjusted input signal, and for upconverting the upconverter 20 input signal to be used by the second summator 32 s1. The second summator 32 s1 is provided for receiving the amplified predistorted signal and the adjusted input signal, and for providing an input adjusted amplified predistorted signal by summing the amplified predistorted signal and the adjusted input signal. The adjustment block 18 j2 is provided for receiving an adjustment input signal, which in this case is the input adjusted amplified predistorted signal, and for providing an unamplified correction signal by adjusting at least one of gain, phase, and delay of the adjustment input signal. The error amplifier 26 e1 is provided for receiving an unamplified error signal, which in this case is the unamplified correction signal, and for providing the correction signal by amplifying the unamplified error signal.

In the embodiment shown in FIG. 5, the first feedback path begins with downconverter 24 c3, provided for receiving a downcoverter input signal, which in this case is the output signal, and for downconverting the downconverter 24 input signal. The adaptor 28 d4 is provided, for receiving the (downconverted) output signal and for providing an adapted signal which is adapted to a change in the electronics environment to be used by one the adjustment block 18 j2.

In the embodiment shown in FIG. 5, the second feedback path begins with downconverter 24 c2 provided for receiving a downcoverter input signal, which in this case is the input adjusted amplified predistorted signal, and for downconverting the downconverter 24 input signal. Adaptor 28 d2 is provided for receiving the (downconverted) input adjusted amplified predistorted signal, and for providing an adapted signal which is adapted to a change in the electronics environment to be used by the adjustment block 18 j1.

In the embodiment shown in FIG. 5, the sensing and control and control begins with the controller 14, which is connected to the feedforward corrector 12, and is connected to the predistorter 10, and is provided for sensing the output signal, the amplified predistorted signal, and the input adjusted amplified predistorted signal, and for controlling adaptor 28 d1, adaptor 28 d2, and adaptor 28 d3.

In alternative embodiments not shown in the drawings, some or all components are implemented in the analog domain, while other or all components are implemented in the digital domain. For example, the predistorter 10 in FIG. 5 can be a conventional digital predistorter 10 or an analog predistorter 10, the analog predistorter 10 is functioning in substantially the same manner as a digital predistorter 10. Those skilled in the art will also understand that the gain/phase/delay adjustment block 18 j1 could be implemented in either digital or analog domain. In analog domain, adjustment block 18 j1 would be located either before or after the upconverter 20 block u2 depending on how j1 was implemented. Similarly adjustment block 18 j2 could be implemented in the analog or digital domain. Depending on whether the summator 22 s1 is analog or digital adjustment block 18 j2 may need to be preceded by a new downconverter 24 and followed by a new upconverter 20 to accommodate the error amplifier 26 e1 which is usually an analog/RF device.

In alternative embodiments not shown in the drawings, some components may be moved, merged, or split. For example, those skilled in the art will also understand that the downconverter 24 c1 and downconverter 24 c3 may be combined into a single downconverter 24 and the downconverted signal split so as to drive the adaptor 28 d1 and adaptor 28 d3. Those skilled in the art will understand that the input signal to downconverter 24 c1 could be moved to directly detect the output of the power amplifier 16 PA, instead of the output of the linearized system summator 22 at s2. Those skilled in the art will also understand that the adaptor 28 blocks could be removed (and corresponding signal detection and downconversion) and a so-called “blind” linearization performed which does not adapt to any changes in the electronics environment.

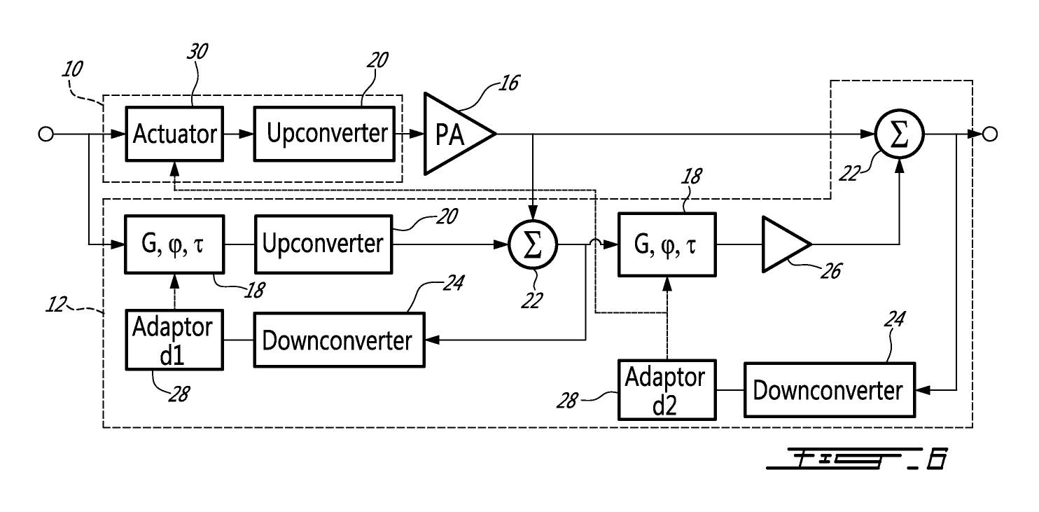

Another exemplary embodiment of the apparatus is shown in FIG. 6. This is substantially similar to FIG. 5. As compared to the embodiment of FIG. 5, a feature of the embodiment of FIG. 6 is that adaptor 28 d1 and adaptor 28 d3 of the embodiment of FIG. 5 are combined into a single adaptor 28 d2 in the embodiment of FIG. 6. In addition to reducing the number of components required, this combination of adaptors may, for example, improve the stability of the adaptation algorithms.

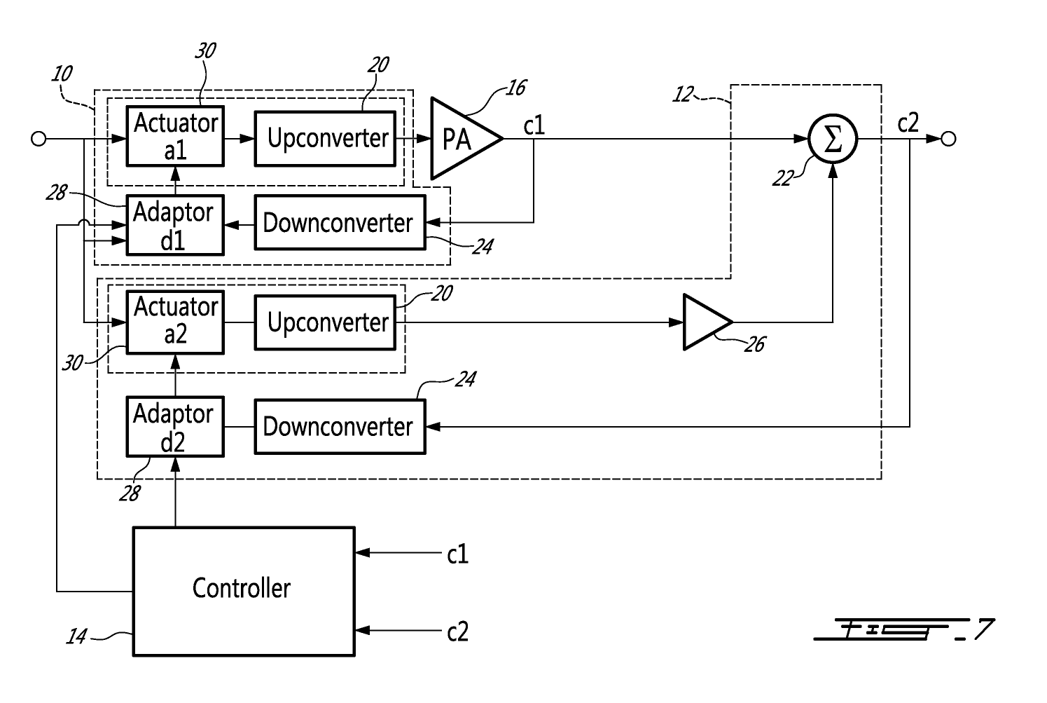

Another exemplary embodiment of the apparatus is shown in FIG. 7. The feedforward stage is changed by removing the reference difference stage and power amplifier 16 PA output detection and adding actuator 30 a2 and associated adaptor 28 d2. A predistortion actuator 30 a2 is applied to the feedforward correction circuit to generate a correction signal using predictive methods.

In alternative embodiments not shown in the drawings, it will be understood by those skilled in the art in view of this disclosure that the output detection c1 could be merged with output detection c2. Although the adaptor 28 d1 might lose the ability to distinguish between the effect of actuator 30 a1 and actuator 30 a2 on the output. Such alternatives are within the scope of the present invention.

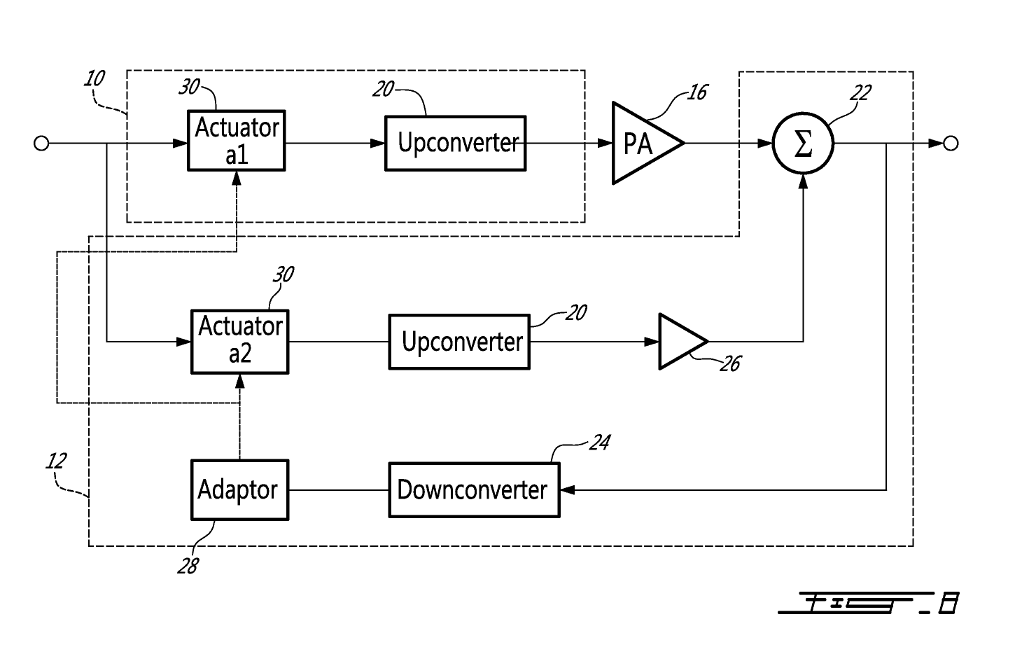

Another exemplary embodiment of the apparatus is shown in FIG. 8. FIG. 8 is substantially similar to FIG. 7. As compared to FIG. 7, the adaptor 28 d1 and adaptor 28 d2 of FIG. 7 are merged into a single adaptor 28 in FIG. 8. In addition to reducing the number of components required, this combination of adaptors may, for example, improve the stability of the adaptation algorithms.

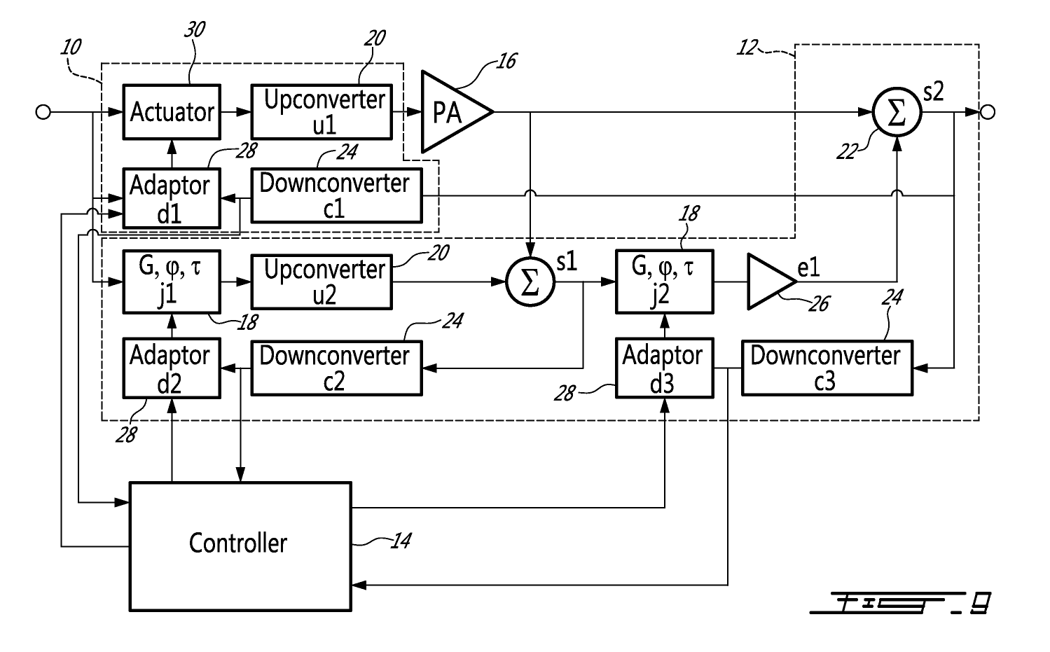

Another exemplary embodiment of the apparatus is shown in FIG. 9. FIG. 9 is substantially similar to FIG. 5. As compared to FIG. 5, the feedback into the predistorter 10 comes from output of summator 22 s2 instead of from the output of the power amplifier 16.

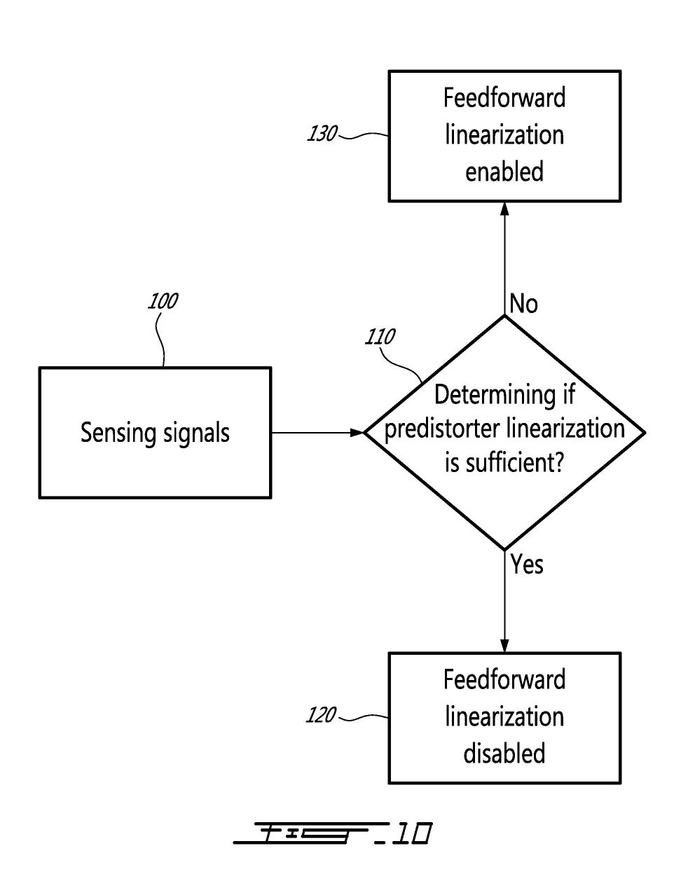

An exemplary embodiment of the method is shown in FIG. 10. As illustrated, the flowchart selectively increases (or enables) or decreases (or disables) the feedforward corrector 12. The flowchart includes four steps: “Sensing Signals” 100, “Determining if predistorter 10 linearization is sufficient?” 110, “Feedforward correction reduced” 120, and “Feedforward correction increased” 130.

At step the “Sensing signals” 100 step, signals are sensed, such as for example, at least one of the output signal, and the amplified predistorted signal. At the “Determining if predistorter linearization is sufficient?” 110 step, the controller 14 determines for example if the linearization required is as much linearization as necessary to predistort the input signal within the predetermined bounds of linearizer efficiency and correction required by the transmitter. If the controller 14 determines that the outcome of step 110 is true, then step “Feedforward correction disabled” 120 ensues and the amount of feedforward correction is decreased or disabled in the feedforward corrector 12. Conversely, if the controller 14 determines that the outcome of step 110 is false, then step “Feedforward correction enabled” 130 ensues and the amount of feedforward correction is increased or enabled in the feedforward corrector 12.

The act of sensing signals includes sensing at least one of the output signal, and the amplified predistorted signal. The sensed signals are then used in the act of determining if predistorter linearization is sufficient enough to predistort the input signal within the predetermined bounds of linearizer efficiency and correction required by the transmitter.

In an alternative embodiment not shown in the drawings, if predistorter linearization is determined to be sufficient enough, the amount of feedforward correction in the feedforward corrector is decreased. Conversely, if predistorter linearization is determined not to be sufficient enough, then the amount of feedforward correction in the feedforward corrector is increased.

In the embodiment shown in FIG. 10, the act of decreasing the amount of feedforward correction in the feedforward corrector includes the act of disabling the feedforward corrector.

In the embodiment shown in FIG. 10, the act of increasing the amount of feedforward correction in the feedforward corrector includes the act of enabling the feedforward corrector.

Operationally, for low output power levels a limited amount of predistortion may be applied to maintain high efficiency. Where models used for digital or analog predistortion fail to account for some transistor or unlinearised power amplifier 16 characteristics the feedforward elements can supplement correction performance. Efficiency drop of feedforward linearization is mitigated by only using feedforward linearization when it is actually needed, as illustrated in the flowchart of FIG. 10, which is one example of the kind of logic implemented by controller 14.

It will be understood by those skilled in the art that a radio may use analog or digital baseband information and that if digital baseband signal is used that the digital signal must at some point be converted to an analog signal for use in the analog RF channel of the radio. While the diagrams herein use a so-called “upconverter 20” and “downconverter 24” to describe the process of converting baseband signal to RF signal there is also an implicit conversion from digital to analog, or vice-versa as needed.

It will also be understood by those skilled in the art that the upconverter 20 and downconverter 24 may be implemented in analog electronics such as using a conventional superheterodyne system, or in digital electronics using digital signal processing based upconversion/downconversion technology.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A combined predistorter and feedforward corrector apparatus suitable for use in a transmitter for improving at least one of power dissipation and linearity in the transmitter, comprising:
a predistorter, for receiving an input signal, and for providing a predistorted signal by performing as much linearization as necessary to predistort the input signal within the predetermined bounds of linearizer efficiency and correction required by the transmitter;
a power amplifier, for receiving the predistorted signal, and for providing an amplified predistorted signal by amplifying the predistorted signal, connected to said predistorter;
a feedforward corrector, for receiving the input signal, and for providing a correction signal by correcting any remaining distortion that the power amplifier produces that the predistorter did not correct; and
a summator, for receiving the amplified predistorted signal and the correction signal, and for providing an output signal by summing the amplified predistorted signal and the correction signal, connected to said feedforward corrector, and connected to said power amplifier.

2. The combined predistorter and feedforward corrector apparatus suitable for use in a transmitter as recited in claim 1, further comprising:
an actuator, for receiving the input signal and for providing at least one of a predistorted input signal and a corrected input signal.

3. The combined predistorter and feedforward corrector apparatus suitable for use in a transmitter as recited in claim 1, further comprising:
an adjustment block, for receiving an adjustment input signal comprising at least one of the input signal and an input adjusted amplified predistorted signal, and for providing a respective one of an adjusted input signal and an unamplified correction signal respectively, by adjusting at least one of gain, phase, and delay of the adjustment input signal.

4. The combined predistorter and feedforward corrector apparatus suitable for use in a transmitter as recited in claim 1, further comprising:
an adaptor, for receiving at least one of the input signal, the output signal, the amplified predistorted signal, and an input adjusted amplified predistorted signal, and for providing an adapted signal which is adapted to a change in the electronics environment to be used by one of an actuator and an adjustment block.

5. The combined predistorter and feedforward corrector apparatus suitable for use in a transmitter as recited in claim 1, further comprising:
an error amplifier, for receiving an unamplified error signal including at least one of an unamplified correction signal, an adjusted input signal, and a corrected input signal, and for providing the correction signal by amplifying the unamplified error signal.

6. The combined predistorter and feedforward corrector apparatus suitable for use in a transmitter as recited in claim 1, further comprising:
a second summator, for receiving the amplified predistorted signal and an adjusted input signal, and for providing an input adjusted amplified predistorted signal by summing the amplified predistorted signal and the adjusted input signal, connected to said adjustment block, and connected to said power amplifier.

7. The combined predistorter and feedforward corrector apparatus suitable for use in a transmitter as recited in claim 1, further comprising:
an upconverter, for receiving an upconverter input signal comprising at least one of the predistorted input signal, an adjusted input signal, and a corrected input signal, and for upconverting the upconverter input signal.

8. The combined predistorter and feedforward corrector apparatus suitable for use in a transmitter as recited in claim 1, further comprising:
a downconverter, for receiving a downconverter input signal comprising at least one of the amplified predistorted signal, the output signal, and an input adjusted amplified predistorted signal, and for downconverting the downconverter input signal.

9. The combined predistorter and feedforward corrector apparatus suitable for use in a transmitter as recited in claim 1, further comprising:
a controller, for sensing at least one of the output signal, and the amplified predistorted signal, the input adjusted amplified predistorted signal, and for controlling at least one adaptor, connected to said predistorter, and connected to said feedforward corrector.

10. A method of controlling the apparatus recited in claim 1, the method comprising the acts of:
sensing signals, including at least one of the output signal, and the amplified predistorted signal;
determining if predistorter linearization is sufficient enough to predistort the input signal within the predetermined bounds of linearizer efficiency and correction required by the transmitter
if predistorter linearization is determined to be sufficient enough, then decreasing the amount of feedforward correction in the feedforward corrector; and
if predistorter linearization is determined not to be sufficient enough, then increasing the amount of feedforward correction in the feedforward corrector.

11. The method as recited in claim 10, wherein the act of decreasing the amount of feedforward correction in the feedforward corrector comprises the act of disabling the feedforward corrector.

12. The method as recited in claim 10, wherein the act of increasing the amount of feedforward correction in the feedforward corrector comprises the act of enabling the feedforward corrector.
